(19) United States
(12) Patent Application Publication
(10) Pub. No.: US 2025/0171296 A1
(43) Pub. Date: May 29, 2025

(54) MEMS ELECTRIC FIELD SENSOR USING RESONANT TORSIONAL SHUTTER AND METHODS OF MANUFACTURING THE SAME

(71) Applicant: INDUSTRY-ACADEMIC COOPERATION FOUNDATION, YONSEI UNIVERSITY, Seoul (KR)

(72) Inventors: Jongbaeg KIM, Seoul (KR); Yohan JUNG, Seoul (KR); Eunhwan JO, Seoul (KR)

(21) Appl. No.: 18/947,281

(22) Filed: Nov. 14, 2024

(30) Foreign Application Priority Data
Nov. 27, 2023 (KR) 10-2023-0166874

(51) Int. Cl. B81B 3/00; B81C 1/00

(52) U.S. Cl. CPC B81B 3/0051; B81C 1/00182; B81B 2201/0292; B81B 2201/033; B81B 2203/0136; B81B 2203/0154; B81B 2203/0163; B81B 2203/04; B81C 2201/0132; B81C 2201/0133; B81C 2201/0181

(57) ABSTRACT

A micro-electromechanical system (MEMS) electric field sensor using a resonant torsional shutter and a method of manufacturing the MEMS electric field sensor are described. A method of manufacturing a micro-electromechanical system (MEMS) electric field sensor according an embodiment includes: forming a metal layer on a wafer having a handle layer, a buried oxide layer arranged on the handle layer, and a device layer arranged on the buried oxide layer; patterning the metal layer to form a plurality of electrical pads thereon, forming a comb drive actuator on the device layer, the comb drive actuator including a sensing electrode and a torsional shutter configured to be resonant torsionally driven; forming a driving space of the torsional shutter in the handle layer; and etching and releasing the buried oxide layer.

### CROSS-REFERENCE TO RELATED APPLICATIONS

This application claims the priority of Korean Patent Application No. 10-2023-0166874 filed on Nov. 27, 2023, in the Korean Intellectual Property Office, the disclosure of which is incorporated herein by reference.

### BACKGROUND OF THE INVENTION

### Field of the Invention

Embodiments described herein relate to a micro-electromechanical system (MEMS) electric field sensor using a resonant torsional shutter and a method of manufacturing the MEMS electric field sensor.

### Background of the Related Art

Electric field sensors have been applied in various industrial fields including monitoring of a high-voltage transmission system, meteorology, motion sensing, etc.

Among the electric field sensors, a field mill electric field sensor configured to sense a change in electric charges induced in a sensing electrode according to a motion of a grounded shutter utilizes micro-electromechanical system (MEMS) technology, and thus, has advantages of miniaturization, batch processing, and low power consumption.

A field mill type MEMS electric field sensor has a grounded shutter driven by lateral, vertical and torsional motions.

Since an intensity of an electric field reaching side surfaces as well as an upper surface of a sensing electrode may vary, a tortional shutter offers an advantage of high sensitivity sensing.

However, in a MEMS electric field sensors in the related art using a method of driving a torsional shutter by a bottom electrode, a complicated manufacturing process such as wafer alignment and anode bonding is needed. In addition, due to presence of the bottom electrode, there are limitations in a torsional angle of a shutter and bidirectional electric field sensing.

In addition, a shutter in a MEMS electric field sensor in the related art having multiple resonance modes is designed in consideration of lateral and vertical motions, and thus, has a structure inappropriate for torsional resonant driving.

Accordingly, MEMS electric field sensors in the related art are not efficient in terms of a torsional resonant motion of a shutter, which is closely related to sensitivity of an electric field sensor.

### SUMMARY OF THE INVENTION

Embodiments may provide a technology related to a micro-electromechanical system (MEMS) electric field sensor capable of inducing torsional driving by a simple process and a method of manufacturing the same.

According to an embodiment, there is provided a method of manufacturing a micro-electromechanical system (MEMS) electric field sensor. The method includes: forming a metal layer on a wafer having a handle layer, a buried oxide layer arranged on the handle layer, and a device layer arranged on the buried oxide layer; patterning the metal layer to form a plurality of electrical pads thereon, forming a comb drive actuator on the device layer, the comb drive actuator including a sensing electrode and a torsional shutter configured to be resonant torsionally driven; forming a driving space of the torsional shutter in the handle layer; and etching and releasing the buried oxide layer.

The forming of the metal layer may include forming the metal layer on the device layer by a sputtering process or an evaporation process.

The wafer may be a wafer (silicon-on-insulator (SOI) wafer, and the metal layer may be made of aluminum.

The forming of the plurality of electrical pads may include forming a first electrical pad on one side of the device layer and a second electrical pad on another side of the device layer by patterning the metal layer.

The forming of the comb drive actuator may include forming the sensing electrode and the torsional shutter by a deep reactive-ion etching (DRIE) process after forming a photoresist pattern on the device layer.

The forming of the comb drive actuator may include forming, on the device layer, the torsional shutter including a movable comb drive, and the sensing electrode including a fixed comb drive disposed alternately with a finger of the movable comb drive.

The sensing electrode may include a first sensing electrode disposed below the first electrical pad and a second sensing electrode disposed below the second electrical pad.

A driving voltage for resonant torsional driving of the torsional shutter may be applied to one of the first electrical pad and the second electrical pad.

The forming of the comb drive actuator may include forming the torsional shutter to include a spring configured to cause torsional driving about a torsional axis.

The forming of the driving space may include forming the driving space using a deep reactive-ion etching (DRIE) process after forming a photoresist pattern on the handle layer, and the releasing may include releasing a portion of a lower portion of the buried oxide layer by performing reactive ion etching (RIE) or wet etching, the portion being exposed by the DRIE process.

According to an embodiment, there is provided a micro-electromechanical system (MEMS) electric field sensor including a wafer including a handle layer having a driving space of a torsional shutter formed therein, a buried oxide layer arranged on the handle layer, and a device layer arranged on the buried oxide layer; and a metal layer arranged on the device layer and patterned to have a plurality of electrical pads disposed thereon, wherein a comb drive actuator are arranged on the device layer, the comb drive actuator including a sensing electrode and a torsional shutter configured to be resonant torsionally driven around a torsional axis.

The torsional shutter may include a movable comb drive.

The torsional shutter may further include a body part having a plurality of first movable fingers of the movable comb drive disposed at both sides and located at a center along the torsional axis.

The torsional shutter may further include a leg part having a plurality of second movable fingers of the movable comb drive disposed at both sides and extending in two parts from an upper side and a lower side of the body part, wherein the upper side and the lower side are two side surfaces of the body part extending along the torsional axis.

The torsional shutter may further include a spring located at centers of the upper side and the lower side of the body part.

The sensing electrode may include: a first sensing electrode arranged at one side with reference to the torsional axis; and a second sensing electrode arranged at another side.

The first sensing electrode may include: a first fixed comb drive disposed alternately with the plurality of first movable fingers and the plurality of second movable fingers; and a first fixed electrode in which the first fixed comb drive is disposed to extend, and wherein the second sensing electrode includes: a second fixed comb drive disposed alternately with the plurality of first movable fingers and the plurality of second movable fingers; and a second fixed electrode in which the second fixed comb drive is disposed to extend.

The first fixed comb drive may include: a plurality of first fixed fingers disposed alternately with the plurality of first movable fingers; and a plurality of second fixed fingers disposed alternately with the plurality of second movable fingers.

The plurality of electrical pads may be arranged on the first fixed electrode, the second fixed electrode, and the plurality of second fixed fingers.

The plurality of first fixed fingers, the plurality of third fixed fingers, and the plurality of first movable fingers may be configured to be longer the plurality of second fixed fingers, the plurality of fourth fixed fingers and the plurality of second movable fingers.

In the present disclosure, a micro-electromechanical system (MEMS) electric field sensor capable of causing torsional driving through a simple manufacturing process may be manufactured, thereby reducing a manufacturing cost and enhancing productivity.

In addition, an electrical pad, i.e., a start electrode to which a driving voltage for resonant torsional driving of a torsional shutter is applied may be arranged on a sensing electrode. Thus, torsional resonant driving of the torsional shutter may occur at a desired frequency. In addition, a resonant torsional motion of the shutter may be efficient, and there may be no limit in a torsional angle of the torsional shutter, and bidirectional electric field sensing may be performed.

In addition, in the present disclosure, differential sensing using two sensing electrodes may be utilized, thereby allowing sensing noise removal and signal amplification.

### BRIEF DESCRIPTION OF THE DRAWINGS

FIGS. 1A to 6B are diagrams for explaining a method of manufacturing a micro-electromechanical system (MEMS) electric field sensor according to an embodiment.

FIG. 7 is a flowchart for explaining the method of manufacturing a MEMS electric field sensor.

FIG. 8 illustrates an example of a MEMS electric field sensor manufactured using the method of manufacturing a MEMS electric field sensor.

FIGS. 9A to 10 are diagrams for explaining a structure of the MEMS electric field sensor.

FIG. 11 is a flowchart for explaining a principle of driving the MEMS electric field sensor.

FIGS. 12 to 16 are diagrams showing results of evaluating characteristics of the MEMS electric field sensor.

FIG. 17 is a diagram illustrating an example of a torsionally driven MEMS sensor in the related art.

### DETAILED DESCRIPTION OF THE PREFERRED EMBODIMENT

Hereinafter, embodiments disclosed herein will be described in detail with reference to the accompanying drawings, and the same or similar elements are designated with the same numeral references, regardless of the numerals in the drawings, and their redundant description will be omitted. In general, a suffix such as “module” and “unit” may be used to refer to elements or components. Use of such a suffix herein is merely intended to facilitate description of the specification, and the suffix itself is not intended to give any special meaning or function. In describing the present disclosure, when a detailed explanation for a related known function or construction is considered to unnecessarily divert the gist of the present disclosure, such explanation has been omitted but would be understood by those skilled in the art. The accompanying drawings are used to help easily understand the technical idea of the present disclosure and it should be understood that the idea of the present disclosure is not limited by the accompanying drawings. The idea of the present disclosure should be construed to extend to any alterations, equivalents and substitutes besides the accompanying drawings.

It will be understood that although the terms first, second, etc. may be used herein to describe various elements, these elements should not be limited by these terms. These terms are generally only used to distinguish one element from another.

It will be understood that when an element is referred to as being “connected with” another element, the element may be connected with the another element or intervening elements may also be present. In contrast, when an element is referred to as being “directly connected with” another element, there are no intervening elements present.

A singular representation may include a plural representation unless it represents a definitely different meaning from the context.

Terms such as “include” or “has” are used herein and should be understood that they are intended to indicate an existence of several components, functions or steps, disclosed in the specification, and it is also understood that greater or fewer components, functions, or steps may likewise be utilized.

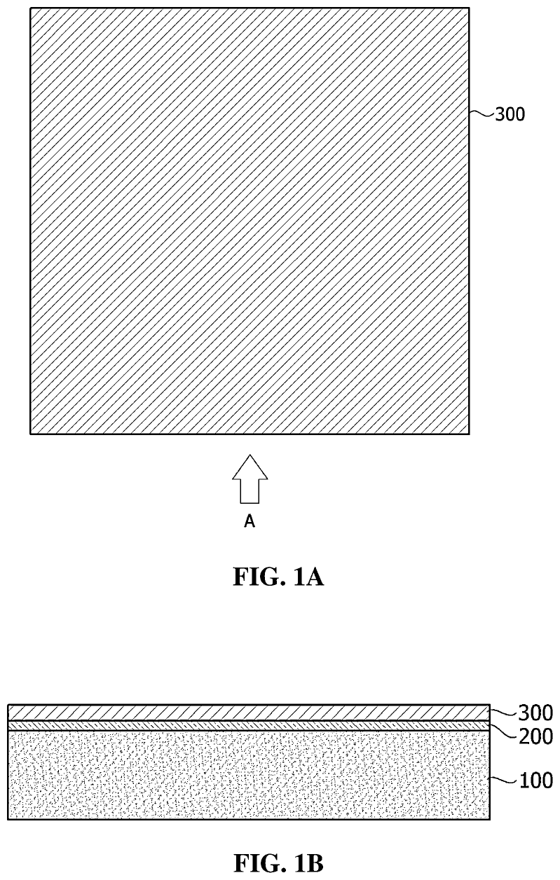

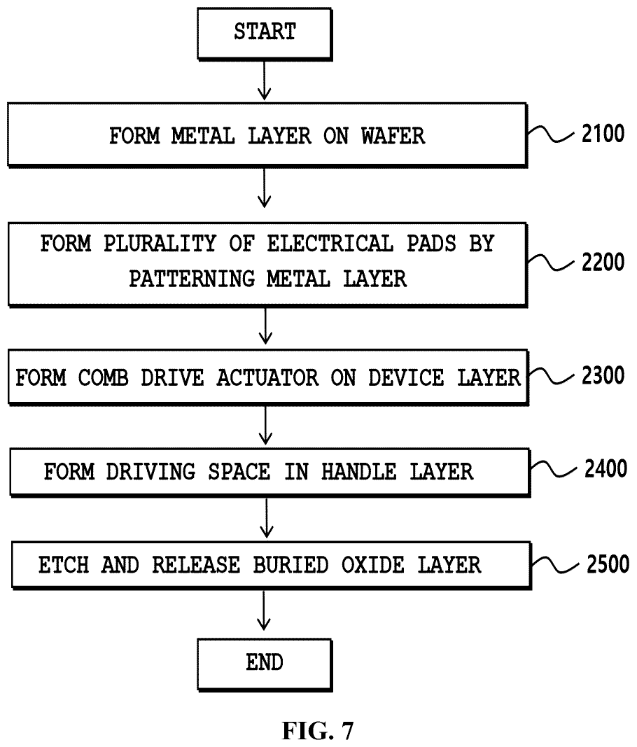

FIGS. 1 to 6 are diagrams for explaining a method of manufacturing a micro-electromechanical system (MEMS) electric field sensor according to an embodiment. FIG. 7 is a flowchart for explaining the method of manufacturing a MEMS electric field sensor.

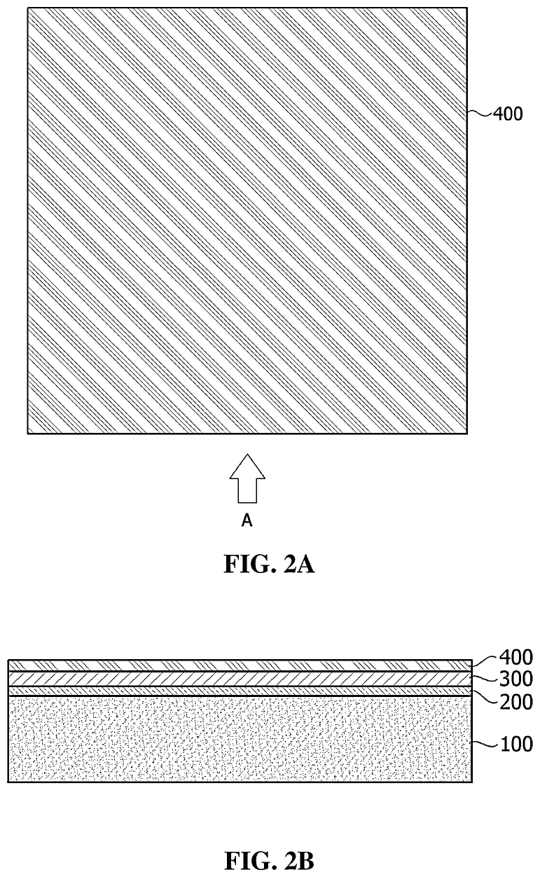

Referring to FIGS. 1A, 1B, 2A, and 2B, in the method of manufacturing a MEMS electric field sensor 30 according to one embodiment, a metal layer 400 may be formed on a wafer having a handle layer 100 thereon, a buried oxide layer 200 disposed on the handle layer 100, and a device layer 300 disposed on the buried oxide layer 200 (2100).

For example, the wafer 10 may be a silicon-on-insulator (SOI) wafer.

For example, operation 2100 may include forming the metal layer 400 on the device layer 300 by performing a sputtering process or an evaporation process.

For example, the metal layer 400 may include aluminum. As another example, the metal layer 400 may include a material having a same function as that of aluminum (e.g., gold, etc.).

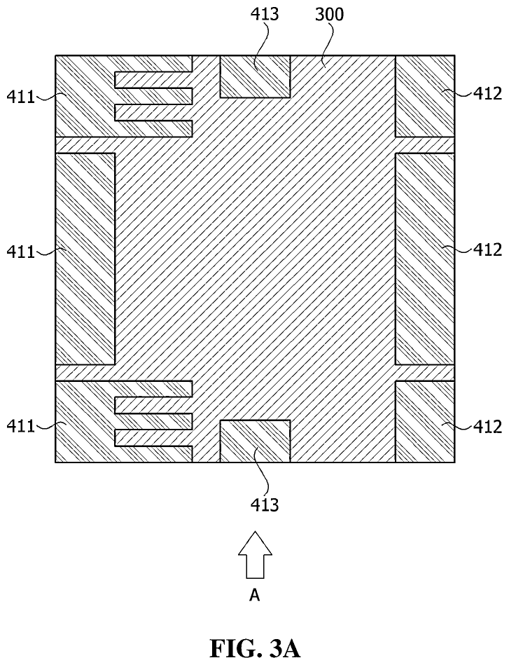

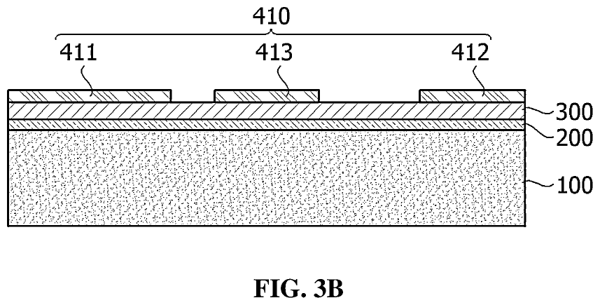

Referring to FIGS. 3A and 3B, the metal layer 400 may be patterned to form a plurality of electrical pads 410 (2200).

For example, operation 2200 may include patterning the metal layer 400 to form a first electrical pad 411 on one side of the device layer 300 and a second electrical pad 412 on another side of the device layer 300.

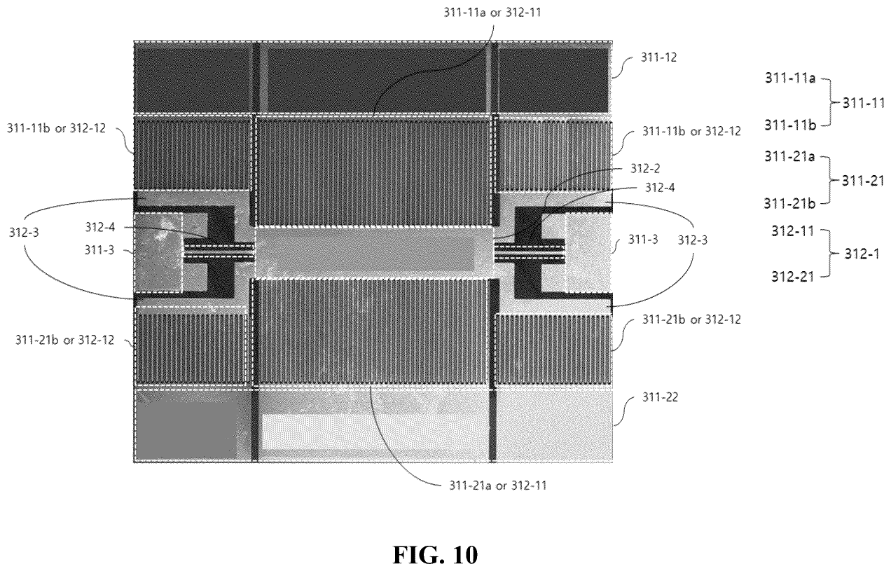

For example, the first electrical pad 411 may be arranged on a first fixed electrode 311-12 and/or a plurality of second fixed fingers 311-11b (see FIG. 10).

As another example, operation 2200 may include patterning the metal layer 400 to arrange a third electrical pad 413 on a portion of both ends of a torsional axis 4100 of the device layer 300.

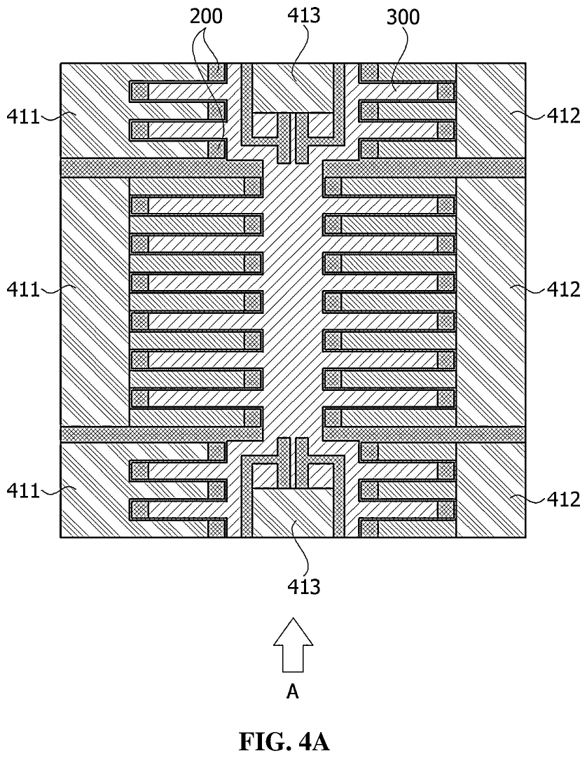

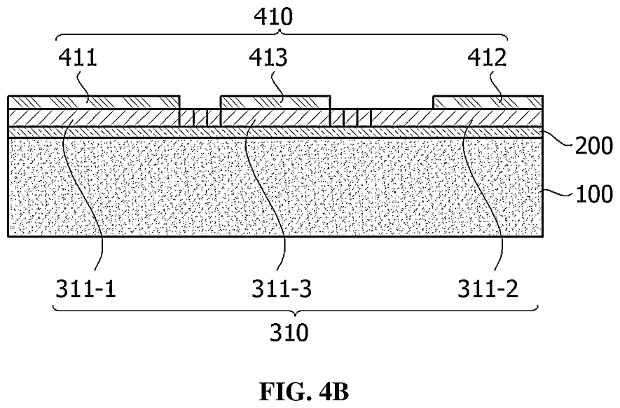

Referring to FIGS. 4A and 4B, a comb drive actuator 310 including a sensing electrode 311 and a torsional shutter 312 which is resonant torsionally driven may be arranged on the device layer 300 (2300).

For example, operation 2300 may include forming the sensing electrode 311 and the torsional shutter 312 using a deep reactive-ion etching (DRIE) process after forming a photoresist pattern on the device layer 300.

For example, operation 2300 may include forming, on the device layer 300, the torsional shutter 312 including a movable comb drive 312-1, and the sensing electrode 311 including fixed comb drives 311-11 and 311-21 disposed alternately with fingers 312-11 and 312-12 of the movable com drive 312-1 (see FIG. 10).

For example, the sensing electrode 311 may include a first sensing electrode 311-1 disposed below the first electrical pad 411 and a second sensing electrode 311-2 disposed below the second electrical pad 412.

The first sensing electrode 311-1 may include a first fixed comb drive 311-11 and the first fixed electrode 311-12.

The second sensing electrode 311-2 may include a second fixed comb drive 311-21 and a second fixed electrode 311-22.

For example, a driving voltage for resonant torsional driving of the torsional shutter 312 may be applied to one of the first electrical pad 411 and the second electrical pad 412.

As another example, when a driving voltage for resonant torsion driving of the torsional shutter 312 is applied to the first electrical pad 411, the first electrical pad 411 may be configured as a starting electrode.

As an example, operation 2300 may include forming the torsional shutter 312 to include a spring 312-4 configured to cause torsional driving around the torsional axis 4100.

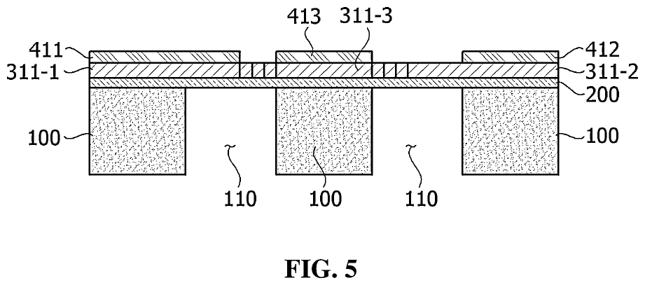

Referring to FIG. 5, a driving space 110 of the torsional shutter 312 may be defined in a handle layer 100 (2400).

As an example, the driving space 110 may mean a space in the handle layer 100 provided to allow the movable comb drive 312-1 to perform a downward torsional motion, when the movable comb drive 312-1 is raised or lowered within a torsional angle range during a resonant torsional motion of the torsional shutter 312.

As an example, operation 2400 may include defining the driving space 110 using a DRIE process after forming a photoresist pattern on the handle layer 100.

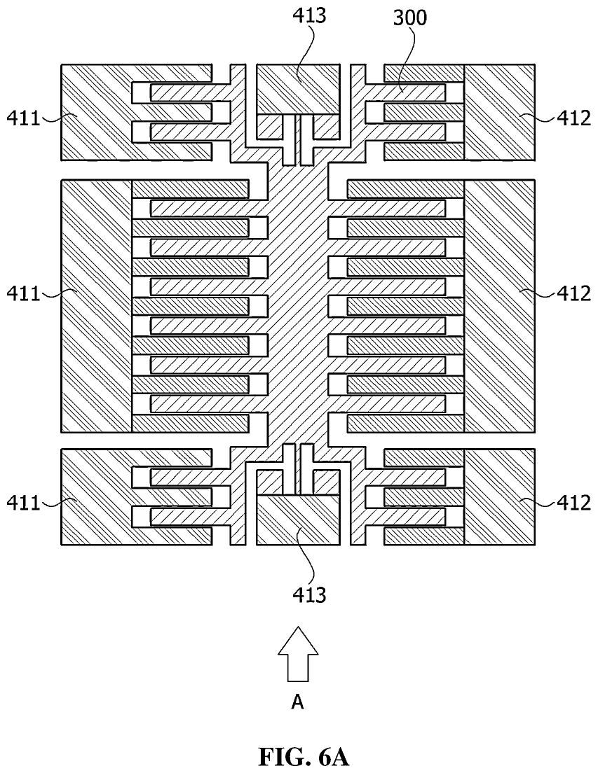

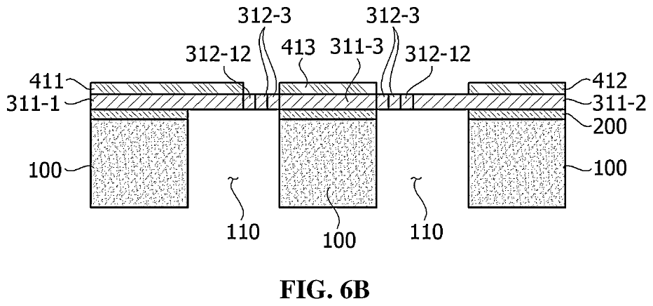

Referring to FIGS. 6A and 6B, the buried oxide layer 200 may be released by being etched (2500).

As an example, operation 2500 may include releasing a part of a lower portion of the buried oxide layer 200 by performing reactive ion etching (RIE) or wet etching, the part being exposed by the DRIE process.

A MEMS electric field sensor manufactured through the method (operations 2100 to 2500) of manufacturing a MEMS electric field sensor as described above may include the wafer including the handle layer 100 in which the driving space 110 of the torsional shutter 312 is defined, the buried oxide layer 200 defined by being etched on the handle layer 100, and the device layer 300 disposed on the buried oxide layer 200, and the metal layer 400 disposed on the device layer 300 and patterned to having a plurality of electrical pads 410 formed thereon.

The comb drive actuator 310 including the sensing electrode 311 and the torsional shutter 312 configured to be resonant torsionally driven around the torsional axis 4100 may be arranged on the device layer 300.

The MEMS electric field sensor 30 capable of causing torsional actuation may be manufactured using a simple manufacturing process through the method (operations 2100 to 2500) of manufacturing a MEMS electric field sensor as described above. Thus, a manufacturing cost may be reduced, and productivity may be improved.

In addition, a plurality of electrical pads 410 to which a driving voltage for resonant torsional driving of the torsional shutter is applied may be arranged on the sensing electrode 311. Thus, resonant torsional driving of the torsional shutter 312 may occur at a desired frequency, a resonant torsional motion of the torsional shutter 312. In addition, a resonant torsional motion of the torsional shutter 312 may be efficiently performed, there is no limitation in a torsional angle of the torsional shutter 312, and bidirectional electric field sensing may be performed.

In addition, the MEMS electric field sensor 30 may utilize differential sensing using the first sensing electrode 311-1 and the second sensing electrode 311-2, thereby allowing sensed noise removal and signal amplification.

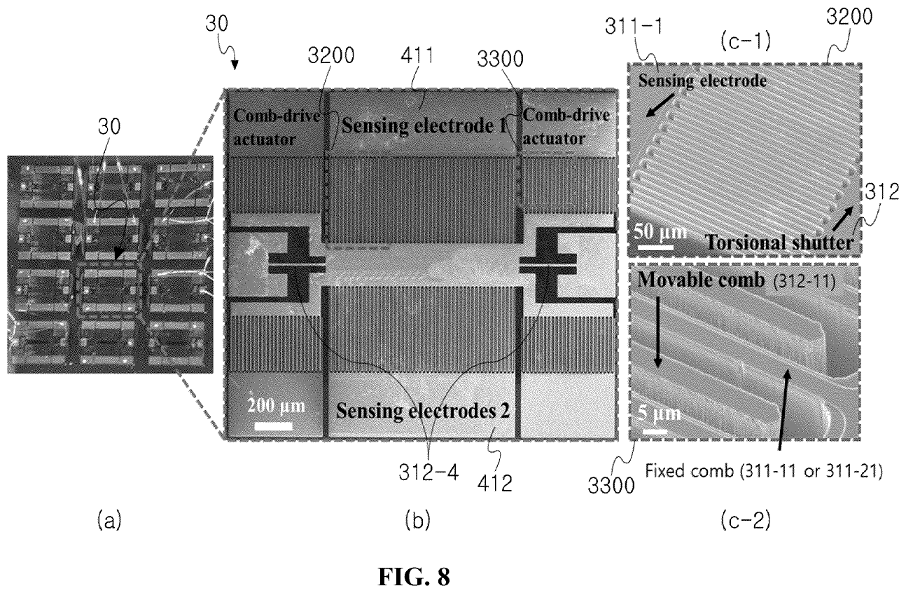

FIG. 8 illustrates an example of a MEMS electric field sensor manufactured using the method of manufacturing a MEMS electric field sensor.

Referring to FIG. 8, the MEMS electric field sensor 30 may be manufactured as shown in (a) in FIG. 8 in a batch process through the manufacturing method described with reference to FIGS. 1 to 7.

(b) in FIG. 8 shows an example of a top view of the MEMS electric field sensor 30. The first electrical pad 411 may be arranged on one side of the wafer 10 and the first sensing electrode 311-1 may be arranged above the wafer 10, and the second electrical pad 412 may be arranged on another side of the wafer 10, and the second sensing electrode 311-2 may be arranged above the wafer 10.

(c-1) in FIG. 8 shows an example in which the fixed fingers 311-11 and 311-21 and the movable comb drive 312-1 are disposed alternately with each other between the sensing electrode 311-1 and the torsional shutter 312.

Referring to (c-1) and a section 3200 and (c-2) and a section 3300 each shown in FIG. 8, the fixed comb drives 311-11 and 311-21 of the sensing electrode 311 and the movable comb drive 312-1 of the torsional shutter 312 may have fingers disposed alternately with each other.

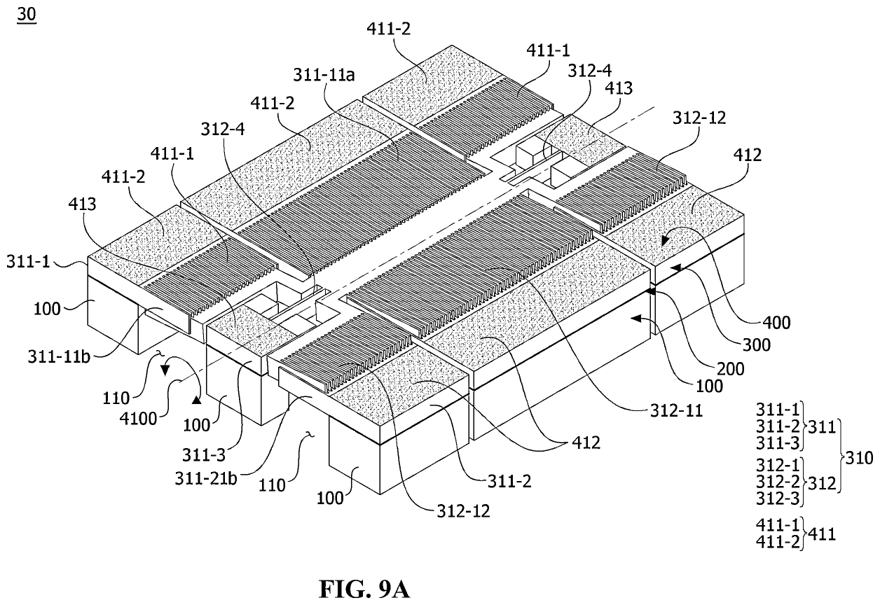

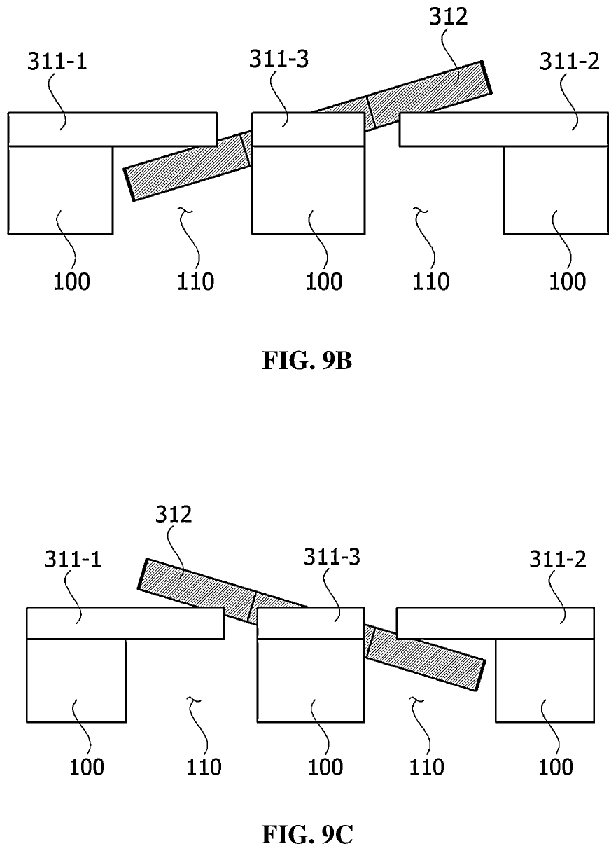

FIGS. 9 to 10 are diagrams for explaining a structure of a MEMS electric field sensor.

FIG. 9A shows an example of a perspective view of the MEMS electric field sensor 30. FIGS. 9B and 9C show examples of torsional driving of the MEMS electric field sensor 30. FIG. 10 shows an example of a plan view of the MEMS electric field sensor 30.

The MEMS electric field sensor 30 may include the wafer 10 including the handle layer 100 on which the driving space 110 of the torsional shutter 312 is defined, the buried oxide layer 200 defined by being etched on the handle layer 100, and the device layer 300 disposed on the buried oxide layer 200, and the metal layer 400 disposed on the device layer 300 and patterned to having a plurality of electrical pads 410 formed thereon.

The comb drive actuator 310 including the sensing electrode 311 and the torsional shutter 312 configured to be resonant torsionally driven around the torsional axis 4100 may be arranged on the device layer 300.

The sensing electrode 311 may include the first sensing electrode 311-1, the second sensing electrode 311-2, and a ground pad 311-3. For example, the sensing electrode 311 may include the first sensing electrode 311-1 arranged at one side and the second sensing electrode 311-2 arranged at another side with reference to the torsional axis 4100.

For example, positive (+) sensed current may be applied to the first sensing electrode 311-1, negative (−) sensed current may be applied to the second sensing electrode 311-2, and the ground pad 311-3 may be grounded.

The first sensing electrode 311-1 may include the first fixed comb drive 311-11 disposed alternately with a plurality of first movable fingers 312-11 and a plurality of second movable fingers 312-12, and the first fixed electrode 322-12 in which the first fixed comb drive 311-11 is disposed to extend.

The first fixed comb drive 311-11 may include a plurality of first fixed fingers 311-11a disposed alternately with the plurality of first movable fingers 312-11 and the plurality of second fixed fingers 311-11b disposed alternately with the plurality of second movable fingers 312-12.

The second sensing electrode 311-2 may include the second fixed comb drive 311-21 disposed alternately with the plurality of first movable fingers 312-11 and the plurality of second movable fingers 312-12, and the second fixed electrode 311-22 in which the second fixed comb drive 311-21 is disposed to extend.

The ground pad 311-3 may be arranged at both end portions of the torsional axis 4100 on the device layer 300.

The torsional shutter 312 may include the movable comb drive 312-1, a body part 312-2, a leg part 312-3, and the spring 312-4.

The movable comb drive 312-1 operates such that an intensity of an electric field reaching the fixed comb drives 311-11 and 311-21 of the sensing electrode 311 varies according to torsional driving of the torsional shutter 312. Thus, a change in induced charges may occur, and be sensed as a current.

That is, referring to FIGS. 9B and 9C, the torsional shutter 312 is torsionally driven in the driving space 110 located below one side and another sides of the body part 312-2 and varies an intensity of an electric field reaching the first sensing electrode 311-1 and the second sensing electrode 311-2. Thus, a change in electric charges induced in the sensing electrode 311 may occur, and be sensed as current.

The movable comb drive 312-1 may include the plurality of first movable fingers 312-11 and the plurality of second movable fingers 312-12.

The body part 312-2 may have the plurality of first movable fingers 312-11 of the movable comb drive 312-1 disposed at both sides and be positioned at a center along the torsional axis 4100.

The leg part 312-3 may have the plurality of second movable fingers 312-12 of the movable comb drive 312-1 disposed at both sides, and extend in two parts from upper and lower sides of the body part 312-2.

For example, the upper and lower sides from which the leg part 312-3 extends may mean two side surfaces of the body part 312-2 which extend along the torsional axis 4100.

The torsional shutter 312 may include the spring 312-4 which causes torsional driving about the torsional axis 4100.

The spring 312-4 may be located at a center of an upper side and a center of a lower side of the body part 312-2. For example, the spring 312-4 may be disposed to extend at centers of two side surfaces extending from the center of the upper side and the center of the lower side of the body part 312-2 in a direction of the torsional axis 4100.

A plurality of electrical pads 410 may include the first electrical pad 411, the second electrical pad 412, and the third electrical pad 413.

The plurality of electrical pads 410 may be arranged on the first fixed electrode 311-12, the second fixed electrode 311-22, and the plurality of second fixed fingers 311-11b.

For example, the first electrical pad 411 may include a finger electrical pad 411-1 disposed on a plurality of second fixed fingers 311-11b and/or a flat electrical pad 411-2 disposed on the first fixed electrode 311-12.

For example, the plurality of first fixed fingers 311-11a, a plurality of third fixed fingers 311-21a, and the plurality of first movable fingers 312-11 may be configured to be longer than the plurality of second fixed fingers 311-11b, a plurality of fourth fixed fingers 311-21b, and the plurality of second movable fingers 312-12.

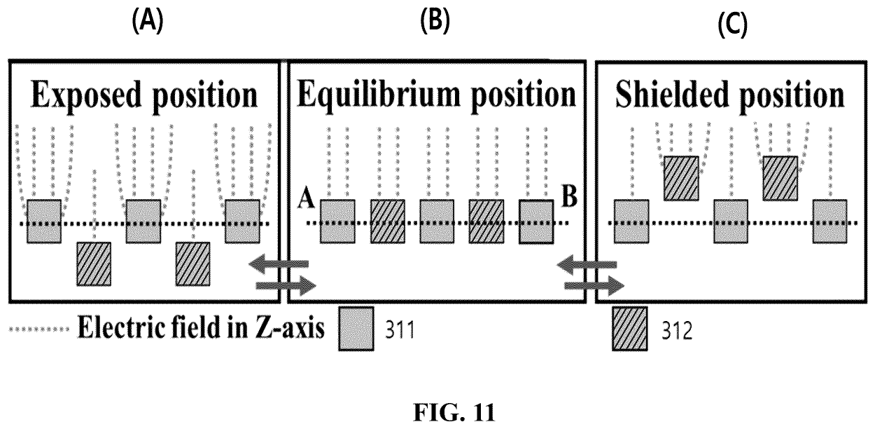

FIG. 11 is a diagram for explaining a principle of driving a MEMS electric field sensor.

In a structure of the comb drive actuator 310 of the MEMS electric field sensor 30, since a start electrode is disposed in the fixed comb drive 311-11 or 311-21 unlike the movable comb drive 312-1, resonant torsional driving of the torsional shutter 312 may be performed as a balance in electrostatic force is broken.

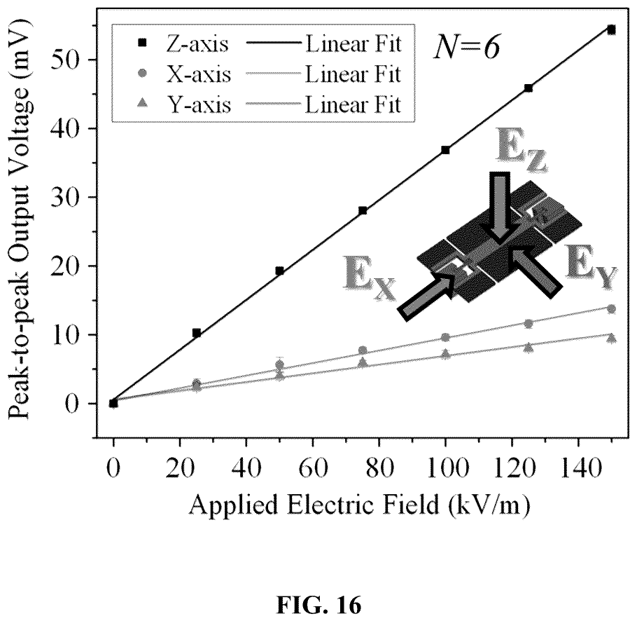

Referring to FIG. 16, according to a driving principle of the MEMS electric field sensor 30, as the torsional shutter 312 which is grounded is torsionally driven by electrostatic force within an out-of-plane electric field of the MEMS electric field sensor 30, an intensity of the electric field reaching the sensing electrode 311 is changed ((A) exposed position, (B) equilibrium position, and (C) shielded position of FIG. 16). Thus, a change in electric charges induced in the sensing electrode 311 occurs.

Accordingly, a change in an amplitude of sensed current according to a change in the induced electric charges occurs at each electrode in the sensing electrode 311, and is sensed as a voltage through current-to-voltage conversion.

Since (A) exposed positions and (C) shielded positions in the first sensing electrode 311-1 and the second sensing electrode 311-2 are opposite to each other according to a position of the torsional shutter 312, Thus, noise may be removed and sensing signals may be amplified using differential sensing.

As a result, sensed current generated in the MEMS electric field sensor 30 within an electric field of a same intensity varies depending on a resonant frequency of the torsional shutter 312, a torsional angle of the torsional shutter 312, and an area of the sensing electrode 311. Thus, this may determine sensitivity of an electric field sensor.

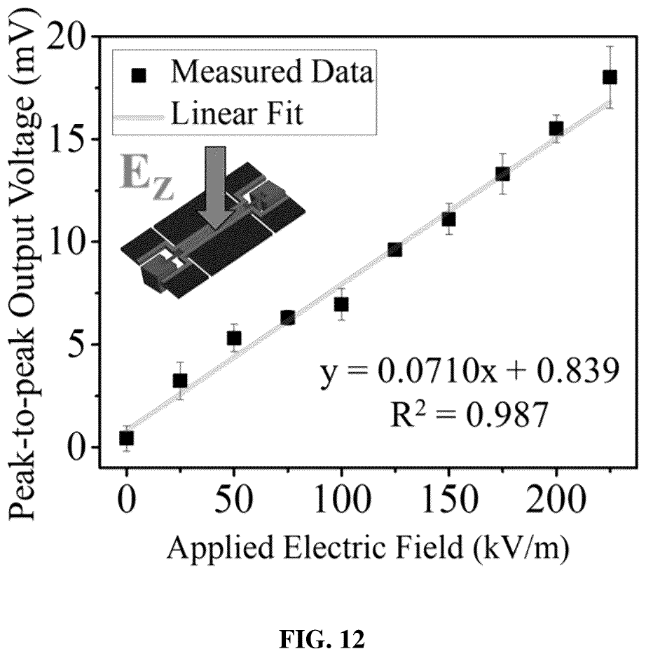

FIGS. 12 to 16 are diagrams showing results of evaluating characteristics of a MEMS electric field sensor.

In detail, FIG. 12 is a diagram showing a sensed voltage and sensor sensitivity of a MEMS electric field sensor according to an intensity of an electric field. This shows an induced voltage with linearity and sensor sensitivity within electric field sensing range from 0 to 225 kV/m.

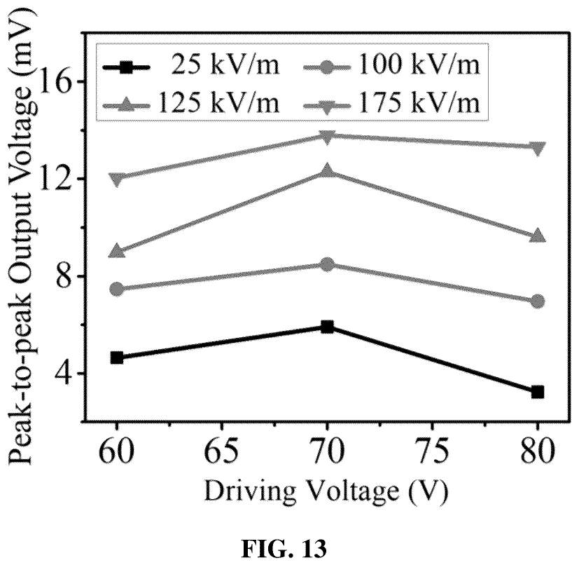

FIG. 13 is a diagram showing a voltage for resonantly driving a torsional shutter, and a sensed voltage of a MEMS electric field sensor according to an intensity of an electric field. This shows a voltage for resonantly driving the torsional shutter which is torsionally driven, and a sensed voltage according to an intensity of an electric field.

A torsional angle of a shutter is changed according to a driving voltage, and when an intensity of an electric field increases, a high sensed voltage is observed.

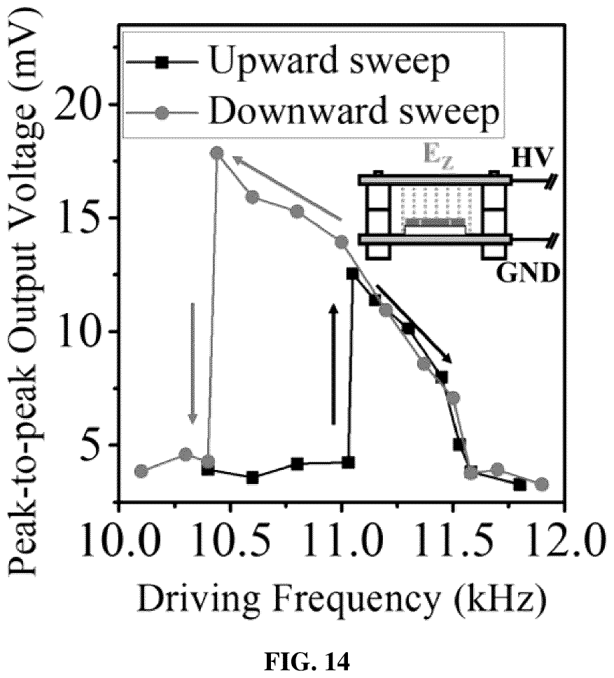

FIG. 14 is a diagram showing a sensed voltage of a MEMS electric field sensor according to a driving frequency of a torsional shutter when driven by a constant voltage. This shows a sensed voltage of the electric field sensor according to a driving frequency of the torsional shutter at a constant electric field intensity and a constant driving voltage. Since a degree of a change in induced electric charges varies depending on a motion of the torsional shutter, a change in a sensed voltage occurs.

Thus, the MEMS electric field sensor 30 may be designed by selecting design parameters such as a length and a width of the torsional shutter 312, a length and a width of the movable comb drive 312-1 or a fixed comb drive 311-11 or 311-21, and a length and a width of the spring 312-4 so that a resonant torsional mode of the torsional shutter 312 occurs at a desired frequency.

In addition, a comb drive actuator 310 with a start electrode may be used for resonance of the torsional shutter 312 instead of using a bottom electrode driving method. Thus, a physical limitation in a torsional angle of a torsional shutter may be eliminated and a process of manufacturing a sensor may be simplified.

In addition, since the MEMS electric field sensor 30 does not include a bottom electrode, bidirectional electric field measurement in an out-of-plane direction of the MEMS electric field sensor 30 may be performed.

The MEMS electric field sensor 30 may reduce sensing noise and utilize signal amplification through differential sensing using two sensing electrodes 311-1 and 311-2.

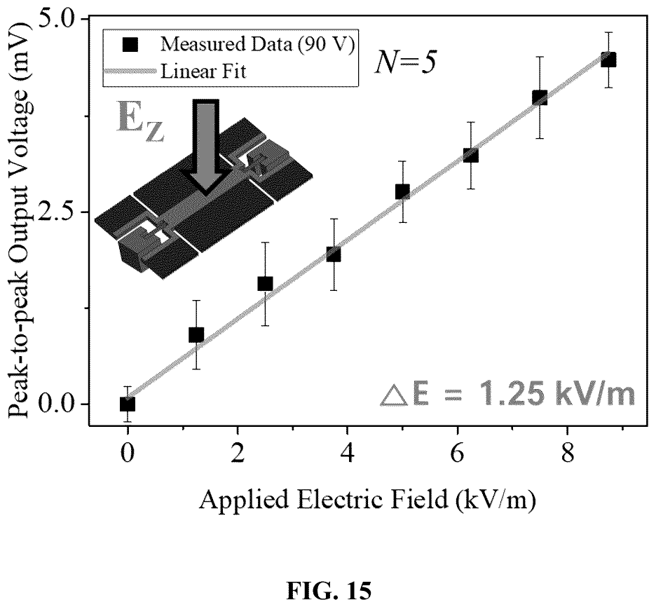

FIG. 15 shows results of evaluating characteristics of a MEMS electric field sensor using a resonantly driven torsional shutter developed in the present disclosure. This shows resolutions of a Z-axis electric field which is capable of being sensed. In a graph in the drawing, repeated measurements and standard deviation are reflected, and a resolution of 1.25 kV/m is shown. A resolution may vary depending on designs of a sensing electrode and a driving electrode in the electric field sensor, and a driving voltage.

FIG. 16 shows cross-axis sensitivity of an electric field sensor for a three-axis electric field. In a graph in the drawing, repeated measurements and standard deviation are reflected, and a highest sensitivity is obtained in an electric field along a Z-axis. A magnitude of an electric field vector applied to the electric field sensor in any direction may be measured using a plurality of sensors. Inter-axis sensitivity may vary depending on designs of a sensing electrode and a driving electrode in the electric field sensor, and a driving voltage.

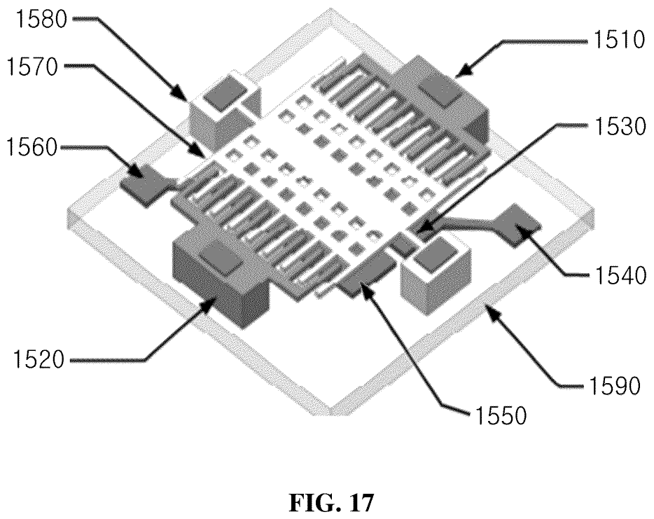

FIG. 17 is a diagram illustrating an example of a torsionally driven MEMS sensor in the related art.

A MEMS sensor in the related art includes a first sensing electrode 1510, a second sensing electrode 1520, a torsional beam 1530, a first bottom electrode 1540, second bottom electrodes 1550 and 1560, a shielding electrode 1570, an anchor 1580, and a substrate 1590.

The MEMS sensor in the related art performs differential sensing using the first and second sensing electrodes 1510 and 1520, performs torsional resonance driving, and operates by utilizing a bottom electrode.

However, an additional process such as wafer alignment and bonding is needed to produce a bottom electrode. Thus, a complex manufacturing process is essentially needed. In addition, as shown in FIG. 17, since the first and second bottom electrodes 1540, 1550, and 1560 are located on a bottom surface of the substrate 1590, a resonant torsional motion of a shutter may be structurally inefficient, a torsional angle of the shutter may be caused to greatly limited during resonant torsional driving, and bidirectional electric field cannot be sensed.

While embodiments of the present disclosure has been explained in relation to its embodiments, it is to be understood that various modifications thereof will become apparent to those skilled in the art upon reading the specification. Therefore, it is to be understood that embodiments disclosed herein are intended to cover such modifications as fall within the scope of the appended claims. Accordingly, the embodiments described herein should be considered in a descriptive sense only and not for purposes of limitation, and the scope of the technical idea of the present disclosure is not limited by these embodiments. Therefore, the above-described embodiments should be considered in a descriptive sense only and not for purposes of limitation. The scope of protection of the present disclosure should be interpreted in accordance with the appended claims, and all technical ideas within the scope will be construed as being included in the scope of the present disclosure.

### Acknowledgement

This work was supported by the National Research Foundation of Korea (NRF) grant funded by the Korea government (MSIT) (Nos. RS-2023-00222166 and RS-2024-00457040).

DESCRIPTION OF SYMBOLS

| | |
|---|---|
| 10: Wafer | 30: MEMS electric field sensor |
| 100: Handle layer | 110: Driving space |
| 200: Buried oxide layer | 300: Device layer |
| 310: Comb drive actuator | 311: sensing electrode |
| 311-1: First sensing electrode | 311-11: First fixed comb drive |
| 311-11a: A plurality of first fixed fingers | 311-11b: A plurality of second fixed fingers |
| 311-12: First fixed electrode | 311-2: Second sensing electrode |
| 311-21: Second fixed comb drive | 311-21a: A plurality of third fixed fingers |
| 311-21b: A plurality of fourth fixed fingers | 311-22: Second fixed electrode |
| 311-3: Ground pad | 312: Torsional shutter |
| 312-1: Movable Comb Drive | 312-11: A plurality of first movable fingers |
| 312-12: A plurality of second movable fingers | 312 -2: Body part |
| 312-3 Leg part | 312-4: Spring |
| 400: Metal layer | 410: A plurality of electrical pads |
| 411: First electrical pad | 411-1: Finger electrical pad |
| 411-2 Flat electrical pad | 412: Second electrical pad |
| 413: Third electrical pad | 4100: Torsional axis |

What is claimed is:

1. A micro-electromechanical system (MEMS) electric field sensor comprising:
a wafer comprising a handle layer having a driving space of a torsional shutter formed therein, a buried oxide layer arranged on the handle layer, and a device layer arranged on the buried oxide layer; and
a metal layer arranged on the device layer and patterned to have a plurality of electrical pads disposed thereon,
wherein a comb drive actuator are arranged on the device layer, the comb drive actuator comprising a sensing electrode and a torsional shutter configured to be resonant torsionally driven around a torsional axis.

2. The MEMS electric field sensor of claim 1, wherein the torsional shutter comprises a movable comb drive.

3. The MEMS electric field sensor of claim 2, wherein the torsional shutter further comprises a body part having a plurality of first movable fingers of the movable comb drive disposed at both sides and located at a center along the torsional axis.

4. The MEMS electric field sensor of claim 3, wherein the torsional shutter further comprises a leg part extending in two parts from an upper side and a lower side of the body part and having a plurality of second movable fingers of the movable comb drive disposed at both sides,
wherein the upper side and the lower side are two side surfaces of the body part extending along the torsional axis.

5. The MEMS electric field sensor of claim 4, wherein the torsional shutter further comprises a spring located at centers of the upper side and the lower side.

6. The MEMS electric field sensor of claim 5, wherein the sensing electrode comprises:
a first sensing electrode arranged at one side with reference to the torsional axis; and
a second sensing electrode arranged at another side.

7. The MEMS electric field sensor of claim 6, wherein the first sensing electrode comprises:
a first fixed comb drive disposed alternately with the plurality of first movable fingers and the plurality of second movable fingers; and
a first fixed electrode in which the first fixed comb drive is disposed to extend, and
wherein the second sensing electrode comprises:
a second fixed comb drive disposed alternately with the plurality of first movable fingers and the plurality of second movable fingers; and
a second fixed electrode in which the second fixed comb drive is disposed to extend.

8. The MEMS electric field sensor of claim 7, wherein the first fixed comb drive comprises:
a plurality of first fixed fingers disposed alternately with the plurality of first movable fingers; and
a plurality of second fixed fingers disposed alternately with the plurality of second movable fingers.

9. The MEMS electric field sensor of claim 8, wherein the plurality of electrical pads are arranged on the first fixed electrode, the second fixed electrode, and the plurality of second fixed fingers.

10. The MEMS electric field sensor of claim 8, wherein the plurality of first fixed fingers, the plurality of third fixed fingers, and the plurality of first movable fingers are configured to be longer the plurality of second fixed fingers, the plurality of fourth fixed fingers and the plurality of second movable fingers.

11. A method of manufacturing a micro-electromechanical system (MEMS) electric field sensor, the method comprising:
forming a metal layer on a wafer having a handle layer, a buried oxide layer arranged on the handle layer, and a device layer arranged on the buried oxide layer;
patterning the metal layer to form a plurality of electrical pads thereon,
forming a comb drive actuator on the device layer, the comb drive actuator comprising a sensing electrode and a torsional shutter configured to be resonant torsionally driven around a torsional axis;
forming a driving space of the torsional shutter in the handle layer; and
etching and releasing the buried oxide layer.

12. The method of claim 11, wherein the forming of the metal layer comprises forming the metal layer on the device layer by a sputtering process or an evaporation process.

13. The method of claim 11, wherein the wafer is a wafer (silicon-on-insulator (SOI) wafer, and the metal layer is made of aluminum.

14. The method of claim 11, wherein the forming of the plurality of electrical pads comprises forming a first electrical pad on one side of the device layer and a second electrical pad on another side of the device layer by patterning the metal layer.

15. The method of claim 11, wherein the forming of the comb drive actuator comprises forming the sensing electrode and the torsional shutter by a deep reactive-ion etching (DRIE) process after forming a photoresist pattern on the device layer.

16. The method of claim 14, wherein the forming of the comb drive actuator comprises forming, on the device layer, the torsional shutter comprising a movable comb drive, and the sensing electrode comprising a fixed comb drive disposed alternately with a finger of the movable comb drive.

17. The method of claim 16, wherein the sensing electrode comprises a first sensing electrode disposed below the first electrical pad and a second sensing electrode disposed below the second electrical pad.

18. The method of claim 7, wherein a driving voltage for resonant torsional driving of the torsional shutter is applied to one of the first electrical pad and the second electrical pad.

19. The method of claim 11, wherein the forming of the comb drive actuator comprises forming the torsional shutter to comprise a spring configured to cause torsional driving about a torsional axis.

20. The method of claim 11, wherein the forming of the driving space comprises forming the driving space using a deep reactive-ion etching (DRIE) process after forming a photoresist pattern on the handle layer, and
the releasing comprises releasing a portion of a lower portion of the buried oxide layer by performing reactive ion etching (RIE) or wet etching, the portion being exposed by the DRIE process.
